(19) United States
(12) Patent Application Publication
(10) Pub. No.: US 2009/0133920 A1
(43) Pub. Date: May 28, 2009

(54) Printed circuit board and manufacturing method of the same

(75) Inventors: Keun-Ho Kim, Seo-gu (KR); Dek-Gin Yang, Cheongwon-gun (KR); Yun-Seok Hwang, Suyeong-gu (KR); Chan-Yeup Chung, Dalseo-gu (KR); Young-Ho Lee, Saha-gu (KR); Cheol-Ho Heo, Busanjin-gu (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/216,374

(22) Filed: Jul. 2, 2008

(30) Foreign Application Priority Data
Nov. 23, 2007 (KR) 10-2007-0120532

(51) Int. Cl. H05K 1/11; H05K 3/10

(52) U.S. Cl. 174/266; 29/852

(57) ABSTRACT

A printed circuit board and a manufacturing method of the same. The method includes forming a circuit board by selectively positioning a heat release layer among multiple insulation layers that have circuit patterns formed on their surfaces, perforating a through-hole that penetrates through one side and the other side of the circuit board, forming a metal film over the heat release layer exposed at an inner wall surface of the through-hole, and forming a plating layer by depositing a conductive metal over an inner wall of the through-hole. By having the heat release layer selectively inserted inside the circuit board, the heat releasing effect may be improved, and the bending strength may be increased. Moreover, a reliable electrical connection can be implemented between the heat release layer and the circuit pattern, making it possible to utilize the heat release layer as a power supply layer or a ground layer.

### CROSS-REFERENCE TO RELATED APPLICATIONS

This application claims the benefit of Korean Patent Application No. 10-2007-0120532 filed with the Korean Intellectual Property Office on Nov. 23, 2007, the disclosure of which is incorporated herein by reference in its entirety.

### BACKGROUND

1. Technical Field

The present invention relates to a printed circuit board and a method of manufacturing the printed circuit board.

2. Description of the Related Art

Recent demands in the printed circuit board are closely related to the trends in the electronics industry and market towards higher speeds and higher densities. To satisfy these demands, various problems may have to be resolved, especially in providing fine-lined circuits, superb electrical properties, high reliability, high-speed signal transfers, and high functionality, etc.

In particular, efficient heat release is becoming increasingly important to improve reliability and prevent malfunctioning in products such as cell phones, servers, and networks, which are trending towards higher speeds, higher power consumption, higher densities, and smaller sizes. High temperatures within a printed circuit board can be a major cause of malfunctions and failures, etc.

Methods in the related art for lowering the temperatures in a printed circuit board may include installing a heat sink in the printed circuit board where high levels of heat are generated, or operating a cooling fan to exhaust the high levels of heat generated in a chip. These methods, however, may require complicated structures and therefore large amounts of space, which may cause an increase in the overall volume of the electronic equipment.

### SUMMARY

An aspect of the invention is to provide a printed circuit board and a method of manufacturing the printed circuit board, in which a heat release layer may be selectively inserted inside the circuit board, to increase heat release and increase bending strength.

Another aspect of the invention is to provide a printed circuit board and a method of manufacturing the printed circuit board, in which a reliable electrical connection is implemented between the heat release layer and the circuit pattern, to enhance heat release, while utilizing the heat release layer as a power supply layer or a ground layer.

One aspect of the invention provides a method of manufacturing a printed circuit board that includes: forming a circuit board, by selectively positioning a heat release layer among multiple insulation layers, on the surfaces of which circuit patterns are formed; perforating a through-hole, which penetrates through one side and the other side of the circuit board; forming a metal film over the heat release layer exposed at an inner wall surface of the through-hole; and forming a plating layer by depositing a conductive metal over an inner wall of the through-hole.

The method may further include, after the perforating of the through-hole, an operation of applying plasma treatment on the through-hole.

Perforating the through-hole can be performed by CNC drilling.

The heat release layer can be made of a material containing aluminum (Al). In this case, the circuit pattern can include copper (Cu), and the forming of the metal film can include forming a zinc (Zn) film over the heat release layer exposed at an inner wall of the through-hole by applying a zincate treatment.

The operation of forming the plating layer may include forming a seed layer over an inner wall of the through-hole, and performing electroplating using the seed layer as an electrode.

After the forming of the plating layer, the method may further include forming an outer-layer circuit pattern on a surface of the circuit board.

The heat release layer may be electrically connected with the plating layer.

Yet another aspect of the invention provides a printed circuit board that includes: a circuit board, which is composed of multiple insulation layers and a heat release layer selectively interposed between the insulation layers, where circuit patterns may be formed on the surfaces of the insulation layers; a through-hole, which penetrates through one side and the other side of the circuit board; a metal film, formed over the heat release layer that is exposed at an inner wall surface of the through-hole; and a plating layer formed over an inner wall of the through-hole.

An outer-layer circuit pattern may additionally be included on a surface of the circuit board.

The heat release layer can be made of a material containing aluminum (Al). In this case, the circuit pattern can include copper (Cu), and the metal film can include a zinc (Zn) film.

The zinc film can be formed by way of a zincate treatment.

The heat release layer may be electrically connected with the plating layer.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flowchart for a method of manufacturing a printed circuit board according to an embodiment of the invention.

FIG. 2, FIG. 3, FIG. 4, FIG. 5, and FIG. 6 are cross-sectional views representing a flow diagram for a method of manufacturing a printed circuit board according to an embodiment of the invention.

FIG. 7 is a cross-sectional view of a printed circuit board according to an embodiment of the invention.

### DETAILED DESCRIPTION

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

The terms used in the present specification are merely used to describe particular embodiments, and are not intended to limit the present invention. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, elements, parts, or combinations thereof disclosed in the specification, and are not intended to preclude the possibility that one or more other features, numbers, steps, actions, elements, parts, or combinations thereof may exist or may be added.

The printed circuit board and method of manufacturing the printed circuit board according to certain embodiments of the invention will be described below in more detail with reference to the accompanying drawings. Those components that are the same or are in correspondence are rendered the same reference numeral regardless of the figure number, and redundant explanations are omitted.

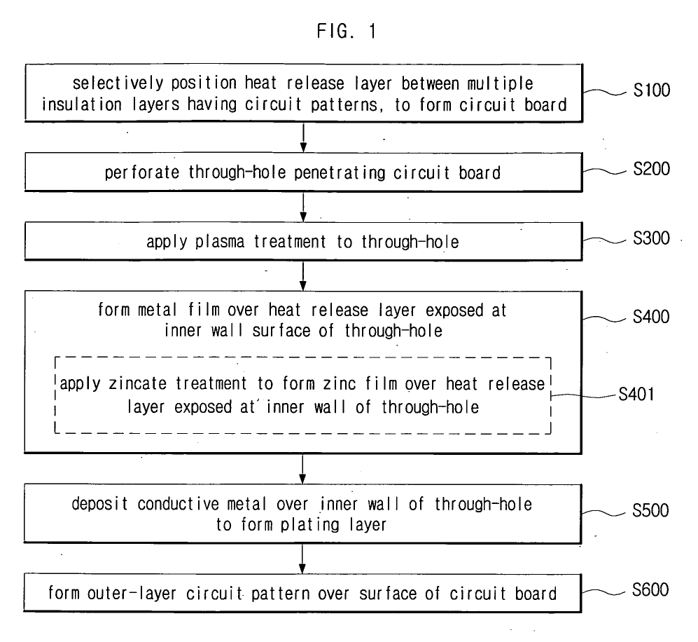

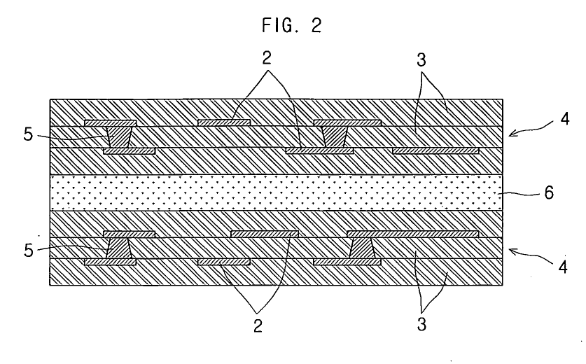

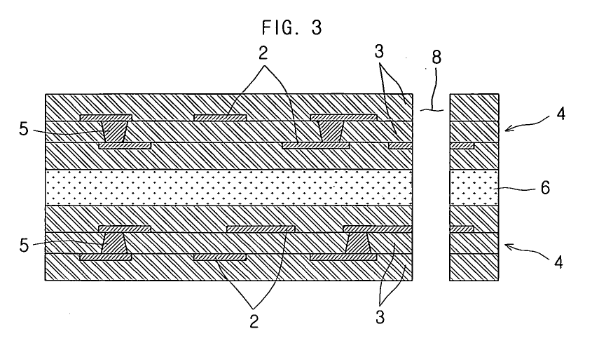

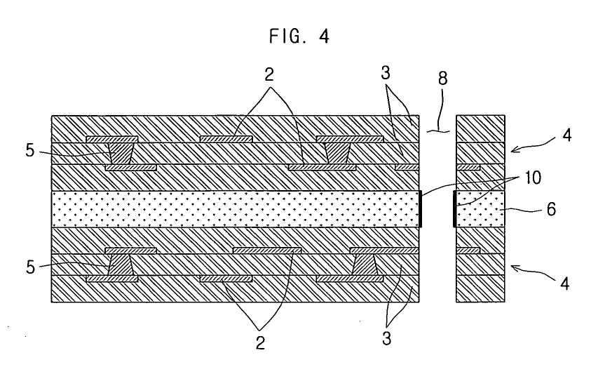

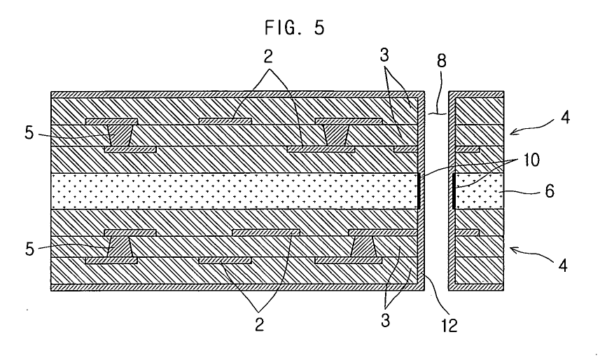

FIG. 1 is a flowchart for a method of manufacturing a printed circuit board according to an embodiment of the invention, while FIG. 2 through FIG. 6 are cross-sectional views representing a flow diagram for a method of manufacturing a printed circuit board according to an embodiment of the invention. In FIGS. 2 to 6, there are illustrated circuit patterns 2, insulation layers 3, a circuit board 4, vias 5, a heat release layer 6, a through-hole 8, a metal film 10, a plating layer 12, and outer-layer circuit patterns 14.

A method of manufacturing a printed circuit board according to this embodiment may include forming a circuit board 4 by selectively positioning a heat release layer 6 between multiple insulation layers 3 that have circuit patterns 2 formed on their surfaces, perforating a through-hole 8 that penetrates one side and the other side of the circuit board 4, forming a metal film 10 over the heat release layer 6 exposed at an inner wall surface of the through-hole 8, and forming a plating layer 12 by depositing a conductive metal over an inner wall of the through-hole 8. As the heat release layer 6 may be selectively inserted inside the circuit board 4, the effectiveness of heat release may be increased, as well as the bending strength. Moreover, a reliable electrical connection may be implemented between the heat release layer 6 and the circuit patterns 2, which can enhance heat release, while the heat release layer 6 may also be utilized as a power supply layer or a ground layer.

In a method of manufacturing a printed circuit board based on this embodiment, a circuit board 4 may first be formed, as illustrated in FIG. 2, by selectively positioning a heat release layer 6 between insulation layers 3 that have circuit patterns 2 formed on the surfaces (S100). The method of forming the circuit board 4 may include, first, stacking an insulation layer 3 over the heat release layer 6, and forming a circuit pattern 2 on the insulation layer 3. Then, another insulation layer 3 may be stacked over the insulation layer 3 on which the circuit pattern 2 has been formed, and another circuit pattern 2 may be formed, the process of which may be repeated to form a multilayered circuit board 4 having a heat release layer 6 inserted within. Of course, vias 5 may also be formed, which electrically connect circuit patterns 2.

While this embodiment is described with one heat release layer 6 inserted between multiple insulation layers having circuit patterns 2, as illustrated in FIG. 2, it is possible to interpose more than one heat release layers 6 between the insulation layers 3, in consideration of the heat releasing performance of the printed circuit board. Furthermore, the heat release layers 6 may be interposed between different multiple insulation layers 3, in consideration of the heat releasing performance.

By thus selectively positioning heat release layers 6 between multiple insulation layers 3, the heat generated in the printed circuit board when operating an electronic device may be effectively released, and the bending strength of the printed circuit board may be increased.

An insulation layer 3 may be formed by coating an insulating material over the heat release layer 6, or by attaching an insulating material in the form of a film. In certain examples, a liquid PI (polyimide) resin may be coated and cured, or a semi-cured prepreg film may be stacked.

The heat release layer 6 can be made of a material having high thermal conductivity, examples of which may include gold, silver, copper, aluminum, etc. In this particular embodiment, aluminum (Al) may be used as the material for the heat release layer 6. Although aluminum is lower in thermal conductivity compared to gold, silver, copper, etc., the difference is not great, and the cost is inexpensive.

The descriptions that follow will be presented for an example in which aluminum is used as the material for the heat release layer 6.

Next, as illustrated in FIG. 3, a through-hole 8 may be perforated that penetrates through the circuit board 4 from one side to the other (S200), and a plasma treatment may be applied to the through-hole 8 (S300). The through-hole 8 may be perforated that penetrates one side and the other side of the circuit board 4, in which the heat release layer 6 is interposed, and a plating layer 12 may be formed on the inner wall of the through-hole 8, in order to implement an interlayer electrical connection between portions of the circuit board 4 separated by the heat release layer 6, as well as to release the heat generated in the circuit board 4 to the atmosphere.

The through-hole 8 may be perforated using a CNC (computer numerical control) drill. In cases where the through-hole 8 is perforated by a drill, portions of the insulation layers 3 may melt and adhere to the inner wall of the through-hole 8. This is referred to as a smear. When a plating layer 12 is formed in the through-hole 8, such smears may lower the adhesion between the insulation layers 3 and the plating layer 12 and thus may have to be removed. A process for removing these smears is referred to as desmearing. If a chemical method is used for removing smears, the process may be referred to as wet desmearing, whereas if a physical method is used, the process may be referred to as dry desmearing.

In cases where wet desmearing is used for removing smears, a portion of the heat release layer 6 exposed at the inner wall of the through-hole may be eroded by the chemicals and may become recessed towards the inner portions of the insulation layers 3. Because of this recess, the heat release layer 6 may be prevented from touching the plating layer 12 formed over the inner wall of the through-hole 8. This can hinder the transfer of heat, whereby the heat releasing effect may be degraded, and can disengage the electrical connection.

In particular, in cases where aluminum (Al) is used for the heat release layer 6, the aluminum may react with the strongly alkaline chemicals used for wet desmearing, and may be excessively recessed inward from the insulation layers 3.

As such, in this embodiment, dry desmearing may be employed, to prevent the recessing of the heat release layer 6. That is, a plasma treatment may be performed on the inner wall of the through-hole 8 to remove smears, whereby the recessing of the heat release layer 6, which may occur with wet desmearing, may be avoided.

The plasma treatment may be performed as follows. When electrically energy is applied while inserting a gas such as argon (Ar), hydrogen (H₂), oxygen (O₂), etc., by itself or in a mixture into a vacuum chamber, collisions between the accelerated electrons may excite the inserted gases into a plasma phase. The ions or radicals, etc., of the gases created in this plasma phase may be collided onto the inner wall of the through-hole 8, by which smears remaining on the inner wall of the through-hole 8 may be removed.

Of course, it is also possible to perforate the through-hole 8 using a laser drill, according to design requirements.

Next, as illustrated in FIG. 4, a metal film 10 may be formed over the heat release layer 6 exposed at the inner wall surface of the through-hole 8 (S400). When the through-hole 8 is perforated in the circuit board 4, a portion of the heat release layer 6 may be exposed at the inner wall surface of the through-hole 8. The heat release layer 6 exposed at the through-hole 8 may be electrically connected with the plating layer 12 formed in a subsequent process over the surface of the inner wall of the through-hole 8, whereby heat generated in the circuit patterns 2 may be released to the atmosphere through the heat release layer 6. Also, as the heat release layer 6 and the plating layer 12 may be electrically connected, it is possible to supply power to the printed circuit board through the heat release layer 6, or to use the heat release layer 6 for grounding.

However, if the heat release layer 6 is exposed by the through-hole 8 to the atmosphere, an oxide layer may be formed over the exposed heat release layer 6, causing the adhesion strength between the heat release layer 6 and the plating layer 12 to be degraded. Therefore, a metal film 10 may be formed, in order to prevent the oxidation of the heat release layer 6 exposed to the atmosphere. The metal film 10 can be made of nickel (Ni), gold (Au), and zinc (Zn), etc.

In cases where the circuit patterns 2 are made of copper (Cu) and the heat release layer 6 is made of aluminum (Al), the method of forming the metal film 10 may include performing a zincate treatment to form a zinc (Zn) film (S401).

Zincate treatment is a process for activating the surface of the aluminum heat release layer 6 exposed to the atmosphere by the through-hole 8. With both oxidation and reduction reactions occurring at the aluminum surface, the aluminum may be dissolved, and the zinc may displace the aluminum. The zinc particles may adhere to the surface of the aluminum, whereby a zinc film may be formed. The zinc film may increase the adhesion strength between the heat release layer 6 made of aluminum and the plating layer 12.

When this zincate treatment is applied, the zinc does not react with the circuit patterns 2 made of copper, due to the ionization tendencies of metals, but does react with the heat release layer 6 made of aluminum. Thus, a photolithography method for selectively forming a zinc film on only the surface of the aluminum can be omitted, whereby the manufacturing process can be shortened and manufacturing costs may be lowered.

Next, as illustrated in FIG. 5, a conductive metal may be deposited on the inner wall of the through-hole 8 to form a plating layer 12 (S500). As described above, by forming a metal film 10 over the heat release layer 6 that is exposed to the atmosphere by the through-hole 8, and forming a plating layer 12 over the inner wall of the through-hole 8, the adhesion strength may be increased between the heat release layer 6 and the plating layer 12. Because of this, a reliable electrical connection can be implemented between the heat release layer 6 and the plating layer 12, and heat generated in the printed circuit board due to the operation of the electronic device can be effectively released through the heat release layer 6. Also, as the heat release layer 6 and the plating layer 12 may be electrically connected, the heat release layer 6 can be utilized for supplying power to the printed circuit board or for grounding, making it unnecessary to form a separate power supply layer for supplying power to the printed circuit board, or a ground layer for grounding the printed circuit board.

A method of forming a plating layer 12 over the inner wall of the through-hole 8 may include forming a seed layer by electroless plating over the inner wall of the through-hole 8, and performing electroplating using the seed layer as an electrode, to form the plating layer 12. In cases where the plating layer 12 is to be formed from copper, the seed layer may be formed by performing electroless copper plating, and then copper electroplating may be performed using the seed layer as an electrode, to form a plating layer 12 made of copper.

Of course, any of various other methods known to those skilled in the art can be employed for depositing the conductive metal, such as evaporation methods and sputtering methods, etc.

Next, as illustrated in FIG. 6, outer-layer circuit patterns 14 may be formed over the surfaces of the circuit board 4 (S600). If there are no circuit patterns 2 already formed on the surfaces of the circuit board 4, plating layers 12 may also be formed over the surfaces of the circuit board 4 during the process of forming the plating layer 12 over the inner wall of the through-hole 8, and then the plating layers 12 formed on the surfaces of the circuit board 4 may be selectively etched, to form the outer-layer circuit patterns 14.

In cases where the plating layer 12 is formed only over the inner wall of the through-hole 8, it is also possible to form the outer-layer circuit patterns 14 over the surfaces of the circuit board 4 using additive processes or subtractive processes.

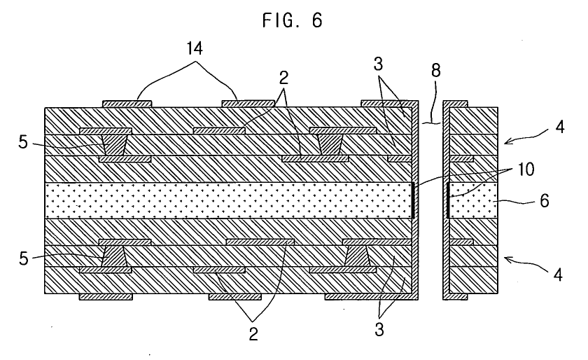

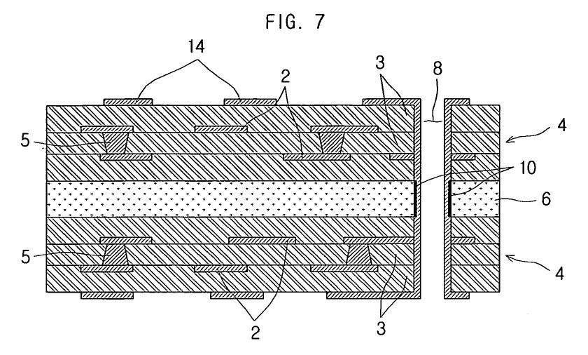

FIG. 7 is a cross-sectional view of a printed circuit board according to an embodiment of the invention. In FIG. 7, there are illustrated circuit patterns 2, insulation layers 3, a circuit board 4, a heat release layer 6, vias 5, a through-hole 8, a metal film 10, and outer-layer circuit patterns 14.

A printed circuit board based on this embodiment may include a circuit board 4, which may include a heat release layer 6 selectively interposed between insulation layers 3 having circuit patterns 2 formed on the surfaces, a through-hole 8 that penetrates through one side and the other side of the circuit board 4, a metal film 10 formed over the heat release layer 6 exposed at an inner wall surface of the through-hole 8, and a plating layer formed over an inner wall of the through-hole 8. By having the heat release layer 6 selectively inserted within the circuit board 4, the heat releasing effect may be improved, and the bending strength may be increased. Also, a reliable electrical connection can be implemented between the heat release layer 6 and the circuit patterns 2, which not only increases the heat releasing effect, but also opens the possibility of using the heat release layer 6 as a power supply layer or a ground layer.

The circuit board 4 may be formed by selectively positioning a heat release layer 6 between multiple insulation layers 3 having circuit patterns 2. The printed circuit board having the inserted heat release layer 6 may effectively release heat, and the bending strength of the printed circuit board may also be increased.

A method of forming the circuit board 4 may include, first, stacking an insulation layer 3 over the heat release layer 6, and forming a circuit pattern 2 on the insulation layer 3. Then, another insulation layer 3 may be stacked over the insulation layer 3 on which the circuit pattern 2 has been formed, and another circuit pattern 2 may be formed, the process of which may be repeated to form a multilayered circuit board 4. Of course, vias 5 may also be formed for electrically connecting the circuit patterns 2.

While this embodiment is described with one heat release layer 6 inserted between multiple insulation layers having circuit patterns 2, as illustrated in FIG. 7, it is possible to position more than one heat release layers 6 between the insulation layers 3, in consideration of the heat releasing performance of the printed circuit board. Furthermore, the heat release layers 6 may be selectively interposed between different multiple insulation layers 3, in consideration of the heat releasing performance.

The heat release layer 6 can be made of a material having high thermal conductivity, examples of which may include gold, silver, copper, aluminum, etc. In this particular embodiment, aluminum (Al) may be used as the material for the heat release layer 6. Although aluminum is lower in thermal conductivity compared to gold, silver, copper, etc., the difference is not great, and the cost is inexpensive.

A plating layer may be formed inside the through-hole 8, to implement an interlayer electrical connection between portions of the circuit board 4 separated by the heat release layer 6, as well as to release the heat generated in the circuit board 4 to the atmosphere.

A metal film 10 may increase the adhesion strength between the heat release layer 6, which is exposed to the atmosphere by the perforation of the through-hole 8, and the plating layer. To be more specific, when the heat release layer 6 is exposed by the through-hole 8 to the atmosphere, an oxide layer may be formed over the exposed heat release layer 6, which may decrease the adhesion strength between the heat release layer 6 and the plating layer 12. Therefore, a metal film 10 may be formed, in order to prevent the oxidation of the heat release layer 6 exposed to the atmosphere. The metal film 10 can be made of nickel (Ni), gold (Au), zinc (Zn), etc.

In cases where the circuit patterns 2 are made of copper (Cu) and the heat release layer 6 is made of aluminum (Al), a zinc (Zn) film may be employed as the metal film 10. The zinc film may be formed over the portion of the heat release layer 6 exposed to the atmosphere, by applying a zincate treatment.

Zincate treatment is a process for activating the surface of the aluminum heat release layer 6 exposed by the through-hole 8 to the atmosphere. With both oxidation and reduction reactions occurring at the aluminum surface, the aluminum may be dissolved, and the zinc may displace the aluminum. The zinc particles may adhere to the surface of the aluminum, whereby a zinc film may be formed. The zinc film may increase the adhesion strength between the heat release layer 6 made of aluminum and the plating layer 12.

When this zincate treatment is applied, the zinc does not react with the circuit patterns 2 made of copper, due to the ionization tendencies of metals, but does react with the heat release layer 6 made of aluminum. Thus, a photolithography method for selectively forming a zinc film on only the surface of the aluminum can be omitted, whereby the manufacturing process can be shortened and manufacturing costs may be lowered.

The plating layer may be electrically connected with the heat release layer 6 such that heat generated in the printed circuit board due to the operation of the electronic device can be released through the heat release layer 6 to the atmosphere. Also, as the heat release layer 6 and the plating layer 12 may be electrically connected, the heat release layer 6 can be utilized for supplying power to the printed circuit board or for grounding, making it unnecessary to form a separate power supply layer for supplying power to the printed circuit board, or a ground layer for grounding the printed circuit board.

If there are no outer-layer circuit patterns 14 already formed on the surfaces of the circuit board 4, plating layers may also be formed over the surfaces of the circuit board 4 during the process of forming the plating layer over the inner wall of the through-hole 8, and then the plating layers formed on the surfaces of the circuit board 4 may be selectively etched, to form the outer-layer circuit patterns 14.

In cases where the plating layer is formed only over the inner wall of the through-hole 8, it is also possible to form the outer-layer circuit patterns 14 over the surfaces of the circuit board 4 using additive processes or subtractive processes.

As set forth above, in certain embodiments of the invention, a heat release layer can be selectively inserted inside the circuit board, to increase heat release and increase bending strength. Moreover, a reliable electrical connection can be implemented between the heat release layer and the circuit pattern, making it possible to utilize the heat release layer as a power supply layer or a ground layer, in addition to enhancing heat release.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method of manufacturing a printed circuit board, the method comprising:
forming a circuit board by selectively positioning a heat release layer among a plurality of insulation layers, the insulation layers having circuit patterns formed on surfaces thereof;
perforating a through-hole penetrating one side and the other side of the circuit board;
forming a metal film over the heat release layer exposed at an inner wall surface of the through-hole; and
forming a plating layer by depositing a conductive metal over an inner wall of the through-hole.

2. The method of claim 1, further comprising, after the perforating of the through-hole:
applying plasma treatment on the through-hole.

3. The method of claim 1, wherein the perforating of the through-hole is performed using a CNC drill.

4. The method of claim 1, wherein the heat release layer is made of a material containing aluminum (Al).

5. The method of claim 4, wherein the circuit pattern is made from copper (Cu), and the forming of the metal film comprises:
forming a zinc (Zn) film over the heat release layer exposed at an inner wall of the through-hole by applying a zincate treatment.

6. The method of claim 1, wherein the forming of the plating layer comprises:
forming a seed layer over an inner wall of the through-hole; and
performing electroplating using the seed layer as an electrode.

7. The method of claim 1, further comprising, after the forming of the plating layer:
forming an outer-layer circuit pattern on a surface of the circuit board.

8. The method of claim 1, wherein the heat release layer is electrically connected with the plating layer.

9. A printed circuit board comprising:
a circuit board composed of a plurality of insulation layers and a heat release layer selectively interposed between the insulation layers, the insulation layers having circuit patterns formed on surfaces thereof;
a through-hole penetrating one side and the other side of the circuit board;
a metal film formed over the heat release layer exposed at an inner wall surface of the through-hole; and
a plating layer formed over an inner wall of the through-hole.

10. The printed circuit board of claim 9, further comprising:
an outer-layer circuit pattern formed on a surface of the circuit board.

11. The printed circuit board of claim 9, wherein the heat release layer is made of a material containing aluminum (Al).

12. The printed circuit board of claim 11, wherein the circuit pattern is made from copper (Cu),
and the metal film comprises a zinc (Zn) film.

13. The printed circuit board of claim 12, wherein the zinc film is formed by a zincate treatment.

14. The printed circuit board of claim 9, wherein the heat release layer is electrically connected with the plating layer.
